(19) United States
(12) Patent Application Publication
(10) Pub. No.: US 2004/0109521 A1
(43) Pub. Date: Jun. 10, 2004

(54) Phase locked loop frequency synthesizer where frequency gain variation controlled oscillator is compensated

(76) Inventors: Min-Su Jeong, Ahnyang-si (KR); Bo-Eun Kim, Yongin-si (KR)

Correspondence Address: SHINJYU GLOBAL IP COUNSELORS, LLP, 1233 20TH STREET, NW, SUITE 700, WASHINGTON, DC, 20036-2680, US

(21) Appl. No.: 10/724,151

(22) Filed: Dec. 1, 2003

(30) Foreign Application Priority Data
Nov. 30, 2002 (KR) 2003-75657

(51) Int. Cl. H03D 3/24

(52) U.S. Cl. 375/376

(57) ABSTRACT

A phase locked loop frequency synthesizer in which frequency gain of a voltage controlled oscillator is compensated is disclosed. The phase locked loop frequency synthesizer measures a frequency gain variation of the voltage controlled oscillator and compensates the variation by controlling phase gain of a phase comparator or voltage gain of a loop filter. Gain characteristics of the voltage controlled oscillator are detected and fed back to control frequency gain of the voltage controlled oscillator, so as to allow the voltage controlled oscillator to have uniform frequency gain. Accordingly, the phase locked loop frequency synthesizer can obtain uniform loop gain irrespective of a frequency gain variation of the voltage controlled oscillator and provide optimum phase noise characteristics and stability.

### BACKGROUND OF THE INVENTION

1. Field of the Invention

The present invention relates to a frequency synthesizer using a phase locked loop and, more particularly, to a frequency synthesizer in which a frequency gain variation of a voltage controlled oscillator is compensated.

2. Background of the Related Art

A frequency synthesizer refers to a circuit or a device that generates a signal of a specific frequency within a predetermined range to output the signal. Most frequency synthesizers employ a phase locked loop (PLL) scheme.

FIG. 1 is a block diagram of a conventional phase locked loop frequency synthesizer. As shown in FIG. 1, the conventional phase locked loop frequency synthesizer includes a phase comparator 101, a loop filter 103, a voltage controlled oscillator 105 and a feedback divider 107.

The phase comparator 101 compares a reference signal Fin applied thereto with a signal outputted from the feedback divider 107 and generates a phase error signal when there is a phase difference between the two signals. This phase difference means a frequency difference between the reference signal Fin and the output signal of the feedback divider 107. The loop filter 103 low-pass-filters the phase error signal outputted from the phase comparator 101 and stabilizes the signal. The voltage controlled oscillator 105 controls the frequency of its output oscillating signal Fout according to the phase error signal inputted from the loop filter 103. The feedback divider 107 is connected between the voltage controlled oscillator 105 and phase comparator 101 to divide the signal Fout outputted from the voltage controlled oscillator 105 at a division rate N.

In the phase locked loop frequency synthesizer shown in FIG. 1, loop gain is proportional to the multiplication result of phase gain of the phase comparator 101, voltage gain of the loop filter 103 and frequency gain of the voltage controlled oscillator but inversely proportional to the division rate N of the feedback divider 107. Accordingly, the phase locked loop frequency synthesizer is designed such that the gains and division rate N have predetermined values to satisfy a predetermined loop gain value.

In the conventional phase locked loop frequency synthesizer, however, the voltage controlled oscillator 105 has a problem that its gain characteristics continuously vary with control voltage or oscillation frequency. In case of using integrated voltage controlled oscillator 105, especially, its gain characteristics vary with a fabrication process, temperature and power voltage. A variation in the gain characteristics of the voltage controlled oscillator changes not only the gain characteristics of the frequency synthesizer but also the phase response characteristics of the frequency synthesizer. In other words, a variation in the gain characteristics of the voltage controlled oscillator 105 affects phase noise and stability of the entire system and deteriorates the performance of the phase locked loop frequency synthesizer.

### SUMMARY OF THE INVENTION

Accordingly, the present invention has been made to substantially obviate one or more problems due to limitations and disadvantages of the related art.

An object of the present invention is to provide a control circuit and method for maintaining a uniform loop gain of a phase locked loop.

Another object of the present invention is to provide a phase locked loop frequency synthesizer which can compensate a variation in frequency gain of a voltage controlled oscillator to uniformly maintain its gain characteristics.

Still another object of the present invention is to a phase locked loop frequency synthesizer which can detect a gain variation of a voltage controlled oscillator and control frequency gain of the voltage controlled oscillator to obtain uniform frequency gain of the voltage controlled oscillator.

To accomplish the above objects, according to one embodiment of the present invention, there is provided a phase locked loop frequency synthesizer, comprising a phase comparator for comparing phases of first and second signals applied thereto with each other and outputting a phase error signal when there is a phase difference between the two signals; a loop filter for filtering the phase error signal outputted from the phase comparator and stabilizing the filtered signal, to output a control signal; a voltage controlled oscillator for controlling frequency gain of a signal output in response to the control signal outputted from the loop filter; a divider for dividing the frequency of the output signal of the voltage controlled oscillator according to a division rate to apply it to the phase comparator as the second signal; a voltage detector for detecting control voltage from the control signal of the voltage controlled oscillator; and a controller for calculating a variation in gain characteristics of the voltage controlled oscillator using the control voltage outputted from the voltage detector and the division rate of the divider and adjusting gain of at least one of the phase comparator, the loop filter and the voltage controlled oscillator, to control gain of a loop composed of the phase comparator, the loop filter, the voltage controlled oscillator and the divider to be substantially uniform.

Preferably, the division rate of the divider is set by the controller.

Preferably, the phase comparator includes a charge pump circuit, and phase gain of the phase comparator is controlled by adjusting a current value of a driving bias current source included in the charge pump circuit.

Also, preferably, the loop filter includes a variable gain amplifier, and voltage gain of the loop filter is controlled by adjusting a gain value of the variable gain amplifier.

The voltage detector is preferably composed of an analog-digital converter.

Preferably, the voltage controlled oscillator includes at least two voltage controlled oscillators, and one of the voltage controlled oscillators is activated according to a control signal provided by the controller.

Also, preferably, the voltage controlled oscillator includes at least one inductor and capacitor that determine a frequency band, and frequency gain of the voltage controlled oscillator is varied by controlling an impedance value of the inductor or capacitor.

In accordance with one embodiment of the present invention, there is also provided a method for detecting frequency gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of: a first step of setting the division rate of the divider to a predetermined first division rate, and detecting control voltage from the control signal; a second step of setting the division rate of the divider to a predetermined second division rate, and detecting control voltage from the control signal; and a third step of calculating the frequency gain of the voltage controlled oscillator using the frequency of the first signal, the control voltages detected at the first and second steps, the first and second division rates.

Preferably, the frequency gain of the voltage controlled oscillator corresponds to Fin×(N1-N2)/(V1-V2) where Fin is the first signal, N1 and N2 denote the first and second division rates, respectively, V1 and V2 represent the control voltages detected at the first and second steps, respectively.

In accordance with another embodiment of the present invention, there is provided a method for detecting frequency gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of: a first step of setting the frequency of the output signal of the voltage controlled oscillator to a predetermined first frequency; a second step of detecting control voltage from the control signal; a third step of controlling the division rate of the divider to vary the frequency of the output signal of the voltage controlled oscillator by a predetermined frequency value, and detecting control voltage from the control signal; a fourth step of calculating the frequency gain of the voltage controlled oscillator using the control voltages detected at the second and third steps and the predetermined frequency value; and a fifth step of comparing the frequency of the output signal of the voltage controlled oscillator with a predetermined second frequency and repeatedly performing the second and fourth steps until the frequency of the output signal has a value identical to the second frequency value.

Preferably, the frequency gain of the voltage controlled oscillator corresponds to Fstep/(V1-V2) where Fstep is the predetermined frequency, V1 denotes the control voltage detected at the second step, and V2 represents the control voltage detected at the third step.

In accordance with another embodiment of the present invention, there is provided a method for detecting frequency gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of: a first step of detecting a control voltage value from the control signal at a predetermined reference frequency; a second step of varying the frequency of the output signal of the voltage controlled oscillator from the reference frequency by a predetermined specific frequency and detecting control voltage from the control signal; a third step of varying the frequency of the output signal of the voltage controlled oscillator from the reference frequency by the specific frequency and detecting control voltage from the control signal; and a fourth step of calculating the frequency gain of the voltage controlled oscillator using the control voltages respectively detected at the second and third steps and the frequency of the output signal.

Preferably, the frequency gain of the voltage controlled oscillator corresponds to (F1-F2)/(V1-V2) where F1 is the frequency of the output signal at the second step, F2 is the frequency of the output signal at the third step, V1 denotes the control voltage detected at the second step, and V2 represents the control voltage detected at the third step.

In accordance with one embodiment of the present invention, there is provided a method for uniformly controlling a loop gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of: a first step of setting the frequency of the output signal of the voltage controlled oscillator to a predetermined first frequency; a second step of detecting control voltage from the control signal; a third step of controlling the division rate of the divider to vary the frequency of the output signal of the voltage controlled oscillator by a predetermined frequency value, and detecting control voltage from the control signal; a fourth step of calculating the frequency gain of the voltage controlled oscillator using the control voltages detected at the second and third steps and the predetermined frequency value; and a fifth step of comparing the frequency of the output signal of the voltage controlled oscillator with a predetermined second frequency and repeatedly performing the second and fourth steps until the frequency of the output signal has a value identical to the second frequency value; and a sixth step of setting a desired output signal frequency of the voltage controlled oscillator, grasping the frequency gain of the voltage controlled oscillator at the corresponding frequency as a value calculated through the first to fifth steps, and controlling gains of the phase comparator and loop filter.

Preferably, frequency gain of the voltage controlled oscillator corresponds to Fstep/(V1-V2) where Fstep is the predetermined frequency, V1 denotes the control voltage detected at the second step, and V2 represents the control voltage detected at the third step.

In accordance with another embodiment of the present invention, there is provided a method for controlling loop gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of: a first step of detecting a control voltage value from the control signal at a predetermined reference frequency; a second step of varying the frequency of the output signal of the voltage controlled oscillator from the reference frequency by a predetermined specific frequency and detecting control voltage from the control signal; a third step of varying the frequency of the output signal of the voltage controlled oscillator from the reference frequency by the specific frequency and detecting control voltage from the control signal; a fourth step of calculating the frequency gain of the voltage controlled oscillator using the control voltages respectively detected at the second and third steps and the frequency of the output signal; and a fifth step of controlling gain of the phase comparator or gain of the loop filter, to control the loop gain to be substantially uniform.

Preferably, the frequency gain of the voltage controlled oscillator corresponds to (F1-F2)/(V1-V2) where F1 is the frequency of the output signal at the second step, F2 is the frequency of the output signal at the third step, V1 denotes the control voltage detected at the second step, and V2 represents the control voltage detected at the third step.

In accordance with another embodiment of the present invention, there is provided a method for controlling frequency gain of a voltage controlled oscillator of a phase locked loop frequency synthesizer to be substantially uniform, the frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of: a first step of detecting a control voltage value from the control signal at a predetermined reference frequency; a second step of varying the frequency of the output signal of the voltage controlled oscillator from the reference frequency by a predetermined specific frequency and detecting control voltage from the control signal; a third step of varying the frequency of the output signal of the voltage controlled oscillator from the reference frequency by the specific frequency and detecting control voltage from the control signal; a fourth step of calculating the frequency gain of the voltage controlled oscillator using the control voltages respectively detected at the second and third steps and the frequency of the output signal; and a fifth step of comparing the calculated frequency gain with a predetermined reference gain and controlling the frequency gain of the voltage controlled oscillator to be substantially uniform.

Preferably, the frequency gain of the voltage controlled oscillator corresponds to (F1-F2)/(V1-V2) where F1 is the frequency of the output signal at the second step, F2 is the frequency of the output signal at the third step, V1 denotes the control voltage detected at the second step, and V2 represents the control voltage detected at the third step.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 is a block diagram of a conventional phase locked loop frequency synthesizer;

FIG. 2 is a block diagram of a phase locked loop frequency synthesizer according to an embodiment of the present invention;

FIG. 3 is a flow chart for showing a procedure of detecting and compensating a frequency gain variation according to control voltage of the voltage controlled oscillator shown in FIG. 2 according to an embodiment of the present invention;

FIG. 4 is a flow chart for showing a procedure of detecting and compensating a frequency gain variation according to control voltage of the voltage controlled oscillator shown in FIG. 2 according to another embodiment of the present invention;

FIG. 5 is a flow chart for showing a procedure of detecting and compensating a frequency gain variation according to control voltage of the voltage controlled oscillator shown in FIG. 2 according to another embodiment of the present invention;

FIG. 6 is a block diagram showing the phase locked loop frequency synthesizer in which a gain variation of the voltage controlled oscillator is compensated according to an embodiment of the present invention in more detail;

FIG. 7 is a block diagram showing a phase locked loop frequency synthesizer in which a gain variation of a voltage controlled oscillator is compensated according to another embodiment of the present invention in more detail; and

FIG. 8 is a block diagram of a gain controllable voltage controlled oscillator according to an embodiment of the present invention.

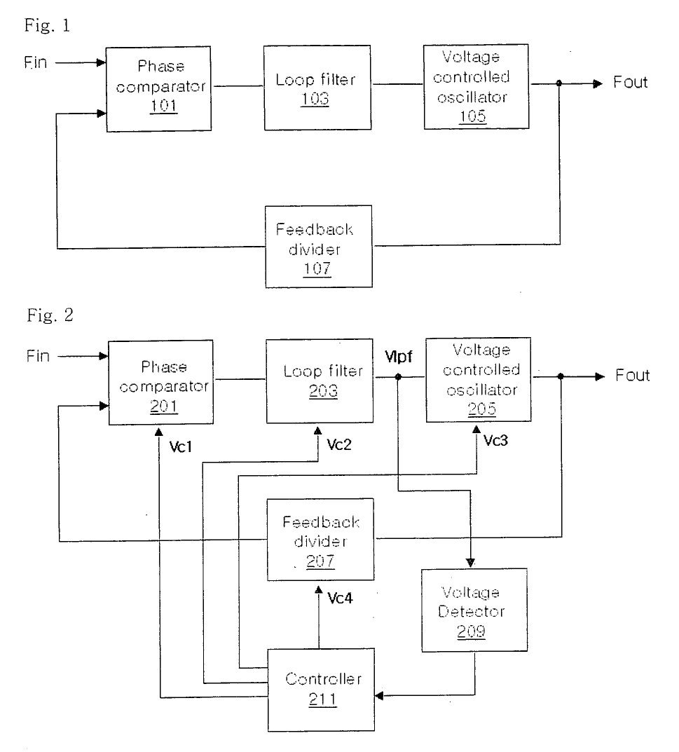

### DETAILED DESCRIPTION OF THE INVENTION

Reference will now be made in detail to the preferred embodiments of the present invention, examples of which are illustrated in the accompanying drawings.

Basic Composition Of a Phase Locked Loop Frequency Synthesizer According to an Embodiment Of the Present Invention

FIG. 2 is a block diagram of a phase locked loop frequency synthesizer according to an embodiment of the present invention. Referring to FIG. 2, the phase locked loop frequency synthesizer according to an embodiment of the invention includes a phase comparator 201, a loop filter 203, a voltage controlled oscillator 205, a feedback divider 207, a voltage detector 209 and a controller 211.

The phase comparator 201 compares the phase of a reference signal Fin with the phase of a signal outputted from the feedback divider 207 and generates a phase error signal when there is a phase difference between the two signals. Phase gain of the phase comparator 201 has a predetermined value in the initial state and it is controlled by a first control signal Vc1 applied from the controller 211.

The loop filter 203 filters the phase error signal generated by the phase comparator 201 and stabilizes the signal. The phase error signal outputted from the loop filter 203 is applied to the voltage controlled oscillator 205 as its control voltage. As well-known in the art, a low pass filter is generally used as the loop filter 203. Voltage gain of the loop filter 203 is set to have a predetermined value in the initial state and it is controlled by a second control signal Vc2 applied from the controller 211.

The voltage controlled oscillator 205 controls the frequency of its output signal Fout according to the control voltage V1pf applied thereto. Frequency gain of the voltage controlled oscillator 205 is determined by a value obtained by dividing a variation in the frequency of the output signal Fout by a variation in the control voltage V1pf. The frequency gain is controlled by a third control signal Vc3 outputted from the controller 211.

The feedback divider 207 divides the frequency of the signal Fout outputted from the voltage controlled oscillator 205. The division rate N of the feedback divider 207 is decided on the basis of a fourth control signal Vc4 outputted from the controller 211.

The voltage detector 209 detects the control voltage V1pf, outputted from the loop filter 203 and applied to the voltage controlled oscillator 205, and outputs it to the controller 211.

The controller 211 detects a frequency gain variation of the voltage controlled oscillator 205 and controls phase gain of the phase comparator 201 or voltage gain of the loop filter 203, to compensate a frequency gain variation of the voltage controlled oscillator 205. Furthermore, the controller 211 detects a variation in the frequency gain characteristics of the voltage controlled oscillator 205 and applies the third control signal Vc3 capable of compensating the detected variation to the voltage controlled oscillator 205 so as to maintain uniform gain characteristics of the voltage controlled oscillator 205.

Although FIG. 2 shows that the controller 211 outputs all of the first, second and third control signals, a variation in the gain characteristics of the voltage controlled oscillator 205 can be compensated even if only one of the first, second and third control signals is applied to the corresponding element. In other words, the gain characteristics variation of the voltage controlled oscillator 205 can be compensated by controlling only the phase gain of the phase comparator 201 without controlling the voltage gain of the loop filter 203 and the frequency gain of the voltage controlled oscillator 205, and the loop gain can be maintained uniform by controlling only the voltage gain of the loop filter 203 or frequency gain characteristics of the voltage controlled oscillator 205.

Method of Detecting and Compensating Gain Characteristics of the Voltage Controlled Oscillator According to an Embodiment of the Present Invention

A method of detecting the gain characteristics of the voltage controlled oscillator 205 and compensating a variation in the gain characteristics according to an embodiment of the present invention is explained below.

In the phase locked loop frequency synthesizer, the output signal frequency Fout is represented by the value obtained by multiplying the input signal frequency Fin by the division rate N of the feedback divider 207. That is, the output signal frequency Fout corresponds to Fin×N in the case that the division rate is N.

The frequency gain of the voltage controlled oscillator 205 can be represented by the value obtained by dividing a variation of the output signal frequency Fout by a variation of the control voltage V1pf. That is, output signal frequency Fout1 when the division rate is N1 is N1×Fin and output signal frequency Fout2 when the division rate is N2 becomes N2×Fin. In the case that control voltages applied to the voltage controlled oscillator 205 are V1pf1 and V1pf2, frequency gain of the voltage controlled oscillator 205 becomes Fin×(N1-N2)/(V1pf1-V1pf2).

Through this method, desired frequency gain of the output frequency Fout can be obtained. Loop gain of the frequency synthesizer can be maintained uniform by controlling the phase gain of the phase comparator 201 or voltage gain of the loop filter 203. More specifically, phase gain of the phase comparator or voltage gain of the loop filter 203 is reduced when frequency gain of the voltage controlled oscillator 205 becomes higher than a predetermined reference gain but the phase gain of the phase comparator 201 or voltage gain of the loop filter 203 is increased in the case that the frequency gain of the voltage controlled oscillator 205 becomes lower than the reference gain so that the loop gain of the frequency synthesizer can maintain a uniform value irrespective of a variation in the frequency gain of the voltage controller oscillator 205.

In accordance with another embodiment of the present invention, the measured frequency gain characteristics of the voltage controlled oscillator 205 can be negatively fed back and controlled to converge the frequency gain of the voltage controlled oscillator 205 on a desired value. Accordingly, the frequency gain of the voltage controlled oscillator 205 can be maintained uniform irrespective of the control voltage or oscillating frequency.

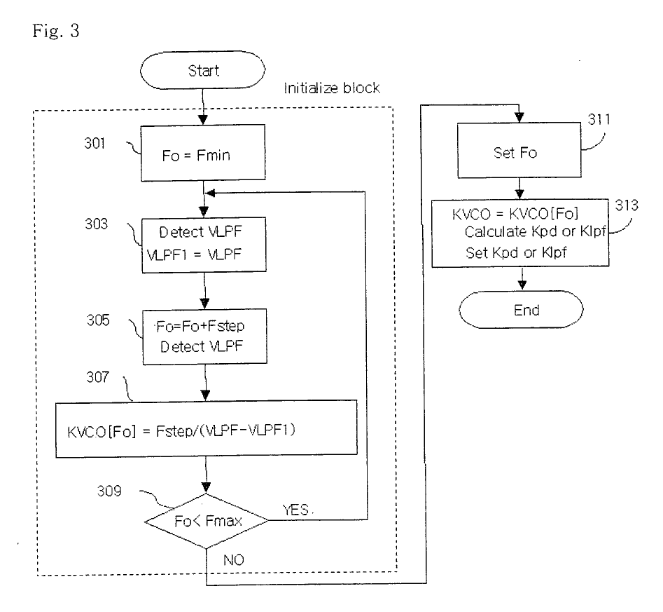

FIG. 3 is a flow chart of a procedure that detects frequency gain characteristics KVCO according to control voltage VLPF of the voltage controlled oscillator 205 and controls phase gain Kpd of the phase comparator 201 and voltage gain K1pf of the loop filter 203 so as to compensate the gain characteristics KVCO of the voltage controlled oscillator 205 according to an embodiment of the present invention.

In the initializing block, an output signal frequency Fo of the voltage controlled oscillator 205 is set to minimum frequency Fmin, at step 301. As described above, since the output signal frequency Fo can be represented by the value obtained by multiplying the input signal frequency Fin by the division rate N of the feedback divider 207, the output signal frequency Fo can be set to the minimum frequency Fmin when the controller 211 sets the division rate N of the feedback divider 207 to a minimum value.

At step 303, a variable VLPF1 is set as the control voltage VLPF. The control voltage VLPF of the voltage controlled oscillator 205 is detected through the voltage detector 209 and applied to the controller 211. Then, the division rate N of the feedback divider 207 is controlled to increase the output signal frequency Fo of the voltage controlled oscillator 205 by a predetermined frequency Fstep and to detect control voltage VLPF in each frequency band, at step 305.

As described above, the frequency gain of the voltage controlled oscillator 205 corresponds to the value obtained by dividing a variation in the output signal frequency Fo by a variation in the control voltage VLPF so that the frequency gain of the voltage controlled oscillator 205 can be found out through the steps 301 and 303. Specifically, the frequency gain of the voltage controlled oscillator 205 corresponds to KVCO [Fo]=Fstep/(VLPF-VLPF1) when the output signal frequency is Fo (step 307).

The steps 303 and 305 are repeated until the output signal frequency Fo of the voltage controlled oscillator 205 becomes maximum frequency Fmax, to detect the gain of the voltage controlled oscillator 205 in each frequency band, at step 309.

Upon completion of the initializing block, a desired output signal frequency Fo is set at step 311. Then, at step 313, phase gain Kpd of the phase comparator 201 or voltage gain K1pf of the loop filter 203, which can satisfy a desired loop gain, can be calculated by setting gain KVCO of the voltage controlled oscillator 205 in case of the output signal frequency Fo to KVCO [Fo] calculated in the initializing block. Accordingly, the controller 211 can control the phase gain Kpd of the phase comparator 201 or voltage gain K1pf of the loop filter 203 through the first or second control signal Vc1 or Vc2 to maintain the entire gain of the phase locked loop frequency synthesizer uniform.

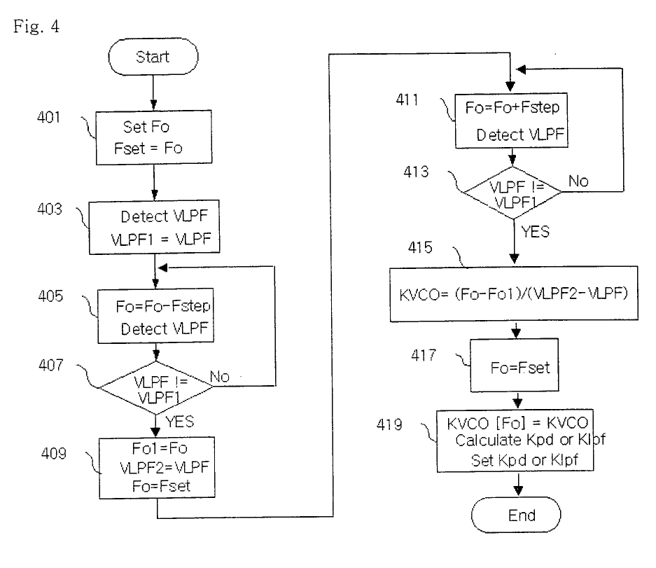

FIG. 4 shows a method for sequentially increasing the output signal frequency of the voltage controlled oscillator 205 from minimum frequency Fmin up to maximum frequency Fmax. In accordance with another embodiment, it is possible to detect the control voltage and calculate frequency gain of the voltage controlled oscillator 205 while decreasing the output signal frequency of the voltage controlled oscillator from maximum frequency Fmax to minimum frequency Fmin.

FIG. 4 is a flow chart of a procedure that detects the frequency gain characteristics according to the control voltage of the voltage controlled oscillator 205 and controls gain Kpd of the phase comparator 201 or gain K1pf of the loop filter 203 in order to maintain a desired loop gain according to another embodiment of the present invention.

Referring to FIG. 4, a desired output signal frequency Fo of the voltage controlled oscillator 205 is set, and a variable Fset is set to the output frequency Fo, at step 401. The voltage detector 207 detects control voltage VLPF of the voltage controlled oscillator 205 and sets variable VLPF1 to the detected voltage VLPF, at step 403. Then, the division rate N of the divider 207 is controlled such that the output signal frequency Fo of the voltage controlled oscillator 205 is reduced by a predetermined frequency Fstep, and control voltage VLPF of the voltage controlled oscillator 205 in this state is detected, at step 405. Step 407 judges whether or not the detected voltage VLPF is identical to the voltage value of variable VLPF1. The step 405 is executed when the two voltage values identical to each other and step 409 is executed when they are not. That is, the output frequency Fo is reduced until control voltage VLPF in the case that the output frequency Fo of the voltage controlled oscillator has been decreased by the predetermined frequency Fstep has a value different from the control voltage VLPF1 at the initially set frequency Fset. At step 409, variables Fo1 and VLPF2 are respectively set to Fo and VLPF that are outputted at step 405, variable Fo is set to the initially set Fset. Accordingly, variable Fo1 is set as a frequency (referred to as ‘first frequency’ hereinafter) that is lower than the initially set output frequency Fset by a predetermined frequency (Fstep or multiples of Fstep) and variable VLPF2 is set as a control voltage value (referred to as ‘first voltage’ hereinafter) of the voltage controlled oscillator 205 at the first frequency.

At step 411, the output frequency Fo of the voltage controlled oscillator 205 is increased from the output frequency Fset initially set by a predetermined frequency Fstep, and control voltage VLPF in this state is detected. At step 413, the detected voltage VLPF is compared with the voltage value of variable VLPF1, and the output frequency of the voltage controlled oscillator 205 is increased by Fstep until the two voltage values become different from each other. When the two voltages have different values, step 415 is executed. Through steps 411 and 413, variable Fo is set to a frequency value (referred to as ‘second frequency’ hereinafter) that is increased by a predetermined frequency (Fstep or multiples of Fstep) from the initially set output frequency Fset, and a control voltage value (referred to as ‘second voltage’ hereinafter) of the voltage controlled oscillator 205 is stored as variable VLPF.

As described above, gain KVCO of the voltage controlled oscillator 205 corresponds to the value obtained by dividing a variation of the output frequency by a variation of the control voltage. Variables Fo1 and VLPF2 are respectively set as the first frequency and first voltage and variables Fo and VLPF are respectively set as the second frequency and second voltage through steps 401 to 413 so that gain KVCO of the voltage controlled oscillator can be calculated as (Fo-F1)/(VLPF2-VLPF) at step 415.

Then, variable Fo is set to the initially set frequency Fset at step 417. At step 419, a variable KVCO [Fo] is set as the frequency gain value KVCO of the voltage controlled oscillator 205, calculated at step 415, and gain of the phase comparator 201 or gain of the loop filter 203 for obtaining a desired loop gain is calculated. Accordingly, the controller 211 can output the first or second control signal Vc1 or Vc2 to maintain uniform loop gain irrespective of a variation in the gain of the voltage controlled oscillator 205.

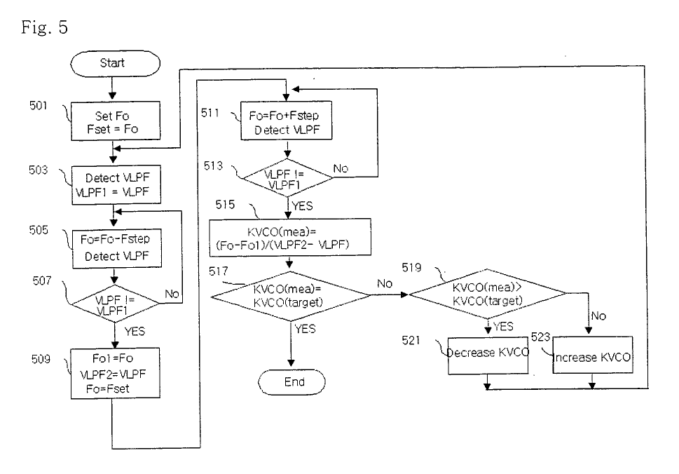

FIG. 5 is a flow chart of a procedure that detects the frequency gain characteristics according to the control voltage of the voltage controlled oscillator shown in FIG. 2 and controls frequency gain of the voltage controlled oscillator 205 through negative feedback according to an embodiment of the present invention. The procedure of controlling frequency gain of the voltage controlled oscillator 205 according to an embodiment of the invention is explained below with reference to FIG. 5. Steps 501 to 509 for detecting the first output frequency and the first voltage, steps 511, 512 and 513 for detecting the second output frequency and the second voltage and step 515 for calculating gain of the voltage controlled oscillator are identical to those explained in FIG. 4 so that explanations therefore are omitted.

Upon calculation of gain KVCO(mea) of the voltage controlled oscillator 205 at the specific frequency Fset, the gain KVCO(mea) is compared with a desired gain KVCO(target) at step 517. When the two gain values are identical to each other, the procedure of controlling gain of the voltage controlled oscillator 205 is finished. In the case that the calculated gain KVCO(mea) of the voltage controlled oscillator 205 is different from the desired gain KVCO(target), the controller 211 outputs the third control signal Vc3 to control the gain of the voltage controlled oscillator. That is, the controller reduces the gain KVCO of the voltage controller oscillator when the calculated gain KVCO(mea) of the voltage controller oscillator is larger than the desired gain KVCO(target) but increases the gain KVCO when it is smaller than the desired gain. Steps 503 to 517 are repeated until desired gain characteristics are obtained.

Concrete Embodiments in which the Method of Compensating the Gain Characteristics of the Voltage Controlled Oscillator According to an Embodiment of the Present Invention is Applied to a Phase Locked Loop Frequency Synthesizer According to an Embodiment of the Present Invention

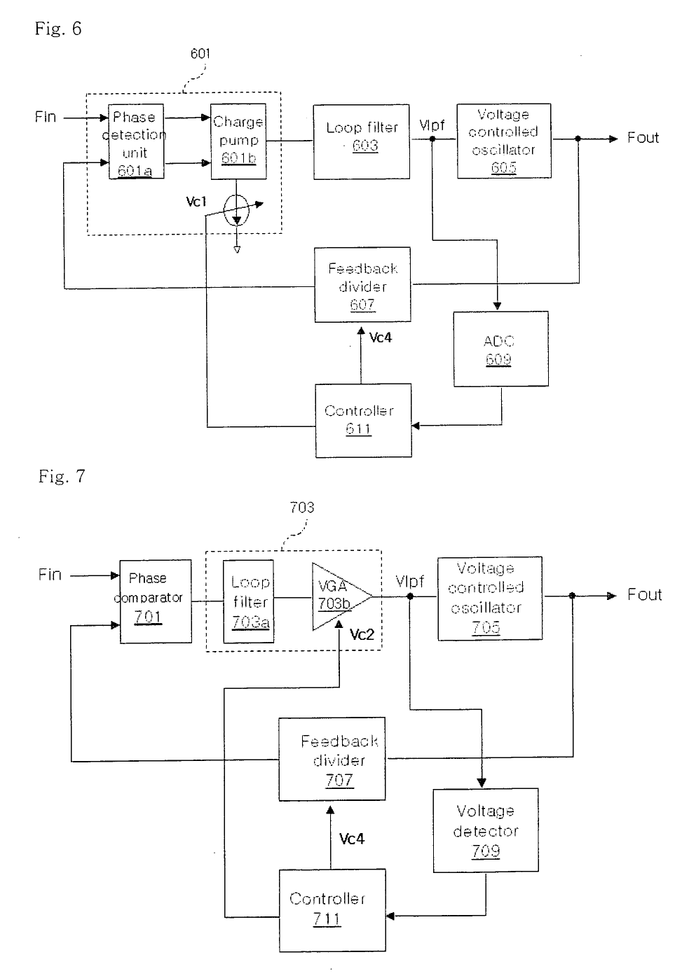

FIG. 6 is a block diagram of a phase locked loop frequency synthesizer in which gain of a phase comparator is controlled using a charge pump to compensate a gain variation of a voltage controlled oscillator according to an embodiment of the present invention. Referring to FIG. 6, the phase locked loop frequency synthesizer according to an embodiment of the present invention includes a phase comparator 601, a loop filter 603, a voltage controlled oscillator 605, a feedback divider 607, a voltage detector 609, and a controller 611.

The phase comparator 601 includes a phase detection unit 601a and a charge pump circuit 601b. The gain of the phase comparator 601 can be controlled by adjusting a driving bias variable current source of the charge pump circuit 601b.

That is, the controller 611 detects gain characteristics of the voltage controlled oscillator 605 and applies a first control signal Vc1 for compensating the detected gain characteristics of the voltage controller oscillator 605 to the bias variable current source, to maintain the entire gain characteristics of the phase locked loop frequency synthesizer uniform.

Furthermore, according to another embodiment of the present invention, the voltage detector 609 can be composed of an analog/digital converter to provide control voltage V1pf of the voltage controller oscillator 609 as a digital signal to the controller 611, as shown in FIG. 6.

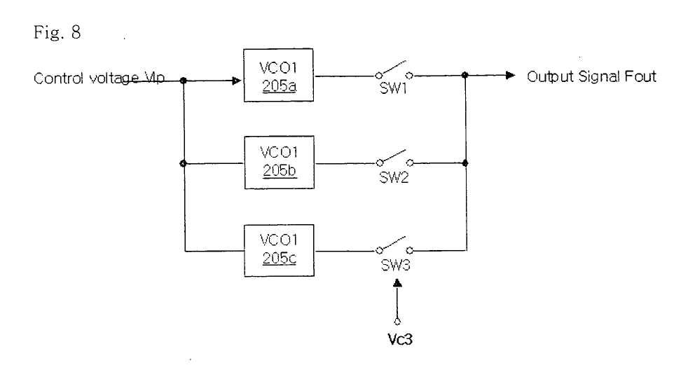

FIG. 7 is a block diagram of a phase locked loop frequency synthesizer in which gain of a loop filter is controlled to compensate gain characteristics of a voltage controlled oscillator according to another embodiment of the present invention. Referring to FIG. 7, the phase locked loop frequency synthesizer according to another embodiment of the invention includes a phase comparator 701, a loop filter 703, a voltage controlled oscillator 705, a feedback divider 707, a voltage detector 709 and a controller 711.

In the phase locked loop frequency synthesizer according to another embodiment of the invention, the loop filter 703 includes a filtering unit 703a and a variable gain amplifier 703b. A variation in the gain characteristics of the voltage controller oscillator 705 can be compensated by controlling gain of the variable gain amplifier 703b.

Specifically, the controller 711 detects the gain characteristics of the voltage controller oscillator 705 and applies a control signal Vc2 for compensating the detected gain characteristics of voltage controller oscillator 705 to the variable gain amplifier 703b of the loop filter 703, to maintain the entire gain of the phase locked loop frequency synthesizer uniform.

FIG. 8 is a block diagram showing an embodiment of detecting gain characteristics of the voltage controller oscillator and feeding back the gain of the voltage controller oscillator to control it. Referring to FIG. 8, the voltage controller oscillator 205 included in the phase locked loop frequency synthesizer shown in FIG. 2 is composed of a plurality of voltage controlled oscillators 205a, 205b and 205c and switches SW1, SW2 and SW3, to control frequency gain of the voltage controller oscillator 205.

Frequency gains of the voltage controlled oscillators 205a, 205b and 205c have different characteristics according to control voltage, and an appropriate voltage controller oscillator is selected according to a third control signal Vc3 applied to the switches SW1, SW2 and SW3.

Specifically, in the case that the frequency gain of the voltage controller oscillator is larger than a desired value, a voltage controller oscillator having smaller frequency gain is selected in order to decrease the frequency gain. On the contrary, a voltage controller oscillator having larger frequency gain is selected when the frequency gain is smaller than the desired value.

Although FIG. 8 shows independent multiple voltage controller oscillators, frequency gain can be changed using a single voltage controller oscillator in such a manner that capacitance or inductance of the oscillation node of an LC-tank voltage controlled oscillator, for example, is varied through a switch. Moreover, while three voltage controlled oscillators having different frequency gain characteristics are shown in FIG. 8, it is well-known in the art that the number of voltage controlled oscillators can be increased or decreased.

### INDUSTRIAL APPLICABILITY

According to the present invention, gain characteristics of the phase locked loop frequency synthesizer can be maintained uniform by detecting a variation in frequency gain of the voltage controlled oscillator and compensating the variation. Furthermore, uniform gain characteristics of the voltage controller oscillator can be maintained by detecting a gain variation of the voltage controlled oscillator and feeding back it to control frequency gain of the voltage controlled oscillator.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A phase locked loop frequency synthesizer, comprising:
a phase comparator for comparing phases of first and second signals applied thereto with each other and outputting a phase error signal when there is a phase difference between the two signals;
a loop filter for filtering the phase error signal outputted from the phase comparator and stabilizing the filtered signal, to output a control signal;
a voltage controlled oscillator for controlling frequency gain of a signal outputted in response to the control signal outputted from the loop filter;
a divider for dividing the frequency of the output signal of the voltage controlled oscillator according to a division rate to apply it to the phase comparator as the second signal;
a voltage detector for detecting control voltage from the control signal of the voltage controlled oscillator; and
a controller for calculating a variation in gain characteristics of the voltage controlled oscillator using the control voltage outputted from the voltage detector and the division rate of the divider, and adjusting gain of at least one of the phase comparator, the loop filter and the voltage controlled oscillator, to control gain of a loop composed of the phase comparator, the loop filter, the voltage controlled oscillator and the divider to be substantially uniform.

2. The phase locked loop frequency synthesizer as claimed in claim 1, wherein the division rate of the divider is set by the controller.

3. The phase locked loop frequency synthesizer as claimed in claim 1, wherein the phase comparator includes a charge pump circuit, and phase gain of the phase comparator is controlled by adjusting a current value of a driving bias current source included in the charge pump circuit.

4. The phase locked loop frequency synthesizer as claimed in claim 1, wherein the loop filter includes a variable gain amplifier, and voltage gain of the loop filter is controlled by adjusting a gain value of the variable gain amplifier.

5. The phase locked loop frequency synthesizer as claimed in claim 1, wherein the voltage detector is composed of an analog-digital converter.

6. The phase locked loop frequency synthesizer as claimed in claim 1, wherein the voltage controlled oscillator includes at least two voltage controlled oscillators, and one of the voltage controlled oscillators is activated according to a control signal provided by the controller.

7. The phase locked loop frequency synthesizer as claimed in claim 1, wherein the voltage controlled oscillator includes at least one inductor and capacitor that determine a frequency band, and frequency gain of the voltage controlled oscillator is varied by controlling an impedance value of the inductor or capacitor.

8. A method for detecting frequency gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of:
a first step of setting the division rate of the divider to a predetermined first division rate, and detecting control voltage from the control signal;
a second step of setting the division rate of the divider to a predetermined second division rate, and detecting control voltage from the control signal; and
a third step of calculating the frequency gain of the voltage controlled oscillator using the frequency of the first signal, the control voltages detected at the first and second steps, the first and second division rates.

9. The method as claimed in claim 8, wherein the frequency gain of the voltage controlled oscillator is calculated by the following equation;
Fin×(N1-N2)/(V1-V2)
where; Fin is the first signal, N1 and N2 denote the first and second division rates, respectively, V1 and V2 represent the control voltages detected at the first and second steps, respectively.

10. A method for detecting frequency gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of:
a first step of setting the frequency of the output signal of the voltage controlled oscillator to a predetermined first frequency;
a second step of detecting control voltage from the control signal;
a third step of controlling the division rate of the divider to vary the frequency of the output signal of the voltage controlled oscillator by a predetermined frequency value, and detecting control voltage from the control signal;
a fourth step of calculating the frequency gain of the voltage controlled oscillator using the control voltages detected at the second and third steps and the predetermined frequency value; and
a fifth step of comparing the frequency of the output signal of the voltage controlled oscillator with a predetermined second frequency and repeatedly performing the second and fourth steps until the frequency of the output signal has a value identical to the second frequency value.

11. The method as claimed in claim 10, wherein the frequency gain of the voltage controlled oscillator is calculated by the following equation;
Fstep/(V1-V2)
Where; Fstep is the predetermined frequency, V1 denotes the control voltage detected at the second step, and V2 represents the control voltage detected at the third step.

12. A method for detecting frequency gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of:
a first step of detecting a control voltage value from the control signal at a predetermined reference frequency;
a second step of varying the frequency of the output signal of the voltage controlled oscillator from the reference frequency by a predetermined specific frequency and detecting control voltage from the control signal;
a third step of varying the frequency of the output signal of the voltage controlled oscillator from the reference frequency by the specific frequency and detecting control voltage from the control signal; and
a fourth step of calculating the frequency gain of the voltage controlled oscillator using the control voltages respectively detected at the second and third steps and the frequency of the output signal.

13. The method as claimed in claim 11, wherein the frequency gain of the voltage controlled oscillator is calculated by the following equation;
(F1-F2)/(V1-V2)
where; F1 is the frequency of the output signal at the second step, F2 is the frequency of the output signal at the third step, V1 denotes the control voltage detected at the second step, and V2 represents the control voltage detected at the third step.

14. A method for controlling a loop gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of:
a first step of setting the frequency of the output signal of the voltage controlled oscillator to a predetermined first frequency;
a second step of detecting control voltage from the control signal;
a third step of controlling the division rate of the divider to vary the frequency of the output signal of the voltage controlled oscillator by a predetermined frequency value, and detecting control voltage from the control signal;
a fourth step of calculating the frequency gain of the voltage controlled oscillator using the control voltages detected at the second and third steps and the predetermined frequency value;
a fifth step of comparing the frequency of the output signal of the voltage controlled oscillator with a predetermined second frequency and repeatedly performing the second and fourth steps until the frequency of the output signal has a value identical to the second frequency value; and
a sixth step of setting a desired output signal frequency of the voltage controlled oscillator, grasping the frequency gain of the voltage controlled oscillator at the corresponding frequency as a value calculated through the first to fifth steps, and controlling gains of the phase comparator and loop filter.

15. The method as claimed in claim 14, wherein the frequency gain of the voltage controlled oscillator is calculated by the following equation;
Fstep/(V1-V2)
Where; Fstep is the predetermined frequency, V1 denotes the control voltage detected at the second step, and V2 represents the control voltage detected at the third step.

16. A method for controlling loop gain of a voltage controlled oscillator of a phase locked loop frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of:
a first step of detecting a control voltage value from the control signal at a predetermined reference frequency;
a second step of varying the frequency of the output signal of the voltage controlled oscillator from the reference frequency by a predetermined specific frequency and detecting control voltage from the control signal;
a third step of varying the frequency of the output signal of the voltage controlled oscillator from the reference frequency by the specific frequency and detecting control voltage from the control signal;
a fourth step of calculating the frequency gain of the voltage controlled oscillator using the control voltages respectively detected at the second and third steps and the frequency of the output signal; and
a fifth step of controlling gain of the phase comparator or gain of the loop filter, to control the loop gain to be substantially uniform.

17. The method as claimed in claim 16, wherein the frequency gain of the voltage controlled oscillator is calculated by the following equation;
(F1-F2)/(V1-V2)
where; F1 is the frequency of the output signal at the second step, F2 is the frequency of the output signal at the third step, V1 denotes the control voltage detected at the second step, and V2 represents the control voltage detected at the third step.

18. A method for controlling frequency gain of a voltage controlled oscillator of a phase locked loop frequency synthesizer to be substantially uniform, the frequency synthesizer including a phase comparator for comparing phases of first and second signals applied thereto with each other and outputting a phase error signal when there is a phase difference between the two signals, a loop filter for filtering the phase error signal outputted from the phase comparator and stabilizing the filtered signal, to output a control signal, a voltage controlled oscillator for controlling frequency gain of a signal output in response to the control signal outputted from the loop filter, and a divider for dividing the frequency of the output signal of the voltage controlled oscillator according to a division rate to apply it to the phase comparator as the second signal, the method comprising the steps of:
a first step of detecting a control voltage value from the control signal at a predetermined reference frequency;
a second step of varying the frequency of the output signal of the voltage controlled oscillator from the reference frequency by a predetermined specific frequency and detecting control voltage from the control signal;
a third step of varying the frequency of the output signal of the voltage controlled oscillator from the reference frequency by the specific frequency and detecting control voltage from the control signal;
a fourth step of calculating the frequency gain of the voltage controlled oscillator using the control voltages respectively detected at the second and third steps and the frequency of the output signal; and
a fifth step of comparing the calculated frequency gain with a predetermined reference gain and controlling the frequency gain of the voltage controlled oscillator to be substantially uniform.

19. The method as claimed in claim 16, wherein the frequency gain of the voltage controlled oscillator is calculated by the following equation;
(F1-F2)/(V1-V2)
where; F1 is the frequency of the output signal at the second step, F2 is the frequency of the output signal at the third step, V1 denotes the control voltage detected at the second step, and V2 represents the control voltage detected at the third step.
